(19) United States
(12) Patent Application Publication
(10) Pub. No.: US 2026/0164777 A1
(43) Pub. Date: Jun. 11, 2026

(54) THREE DIMENSIONAL TRANSISTORS WITH IMPROVED CHARACTERISTICS AND METHODS OF FABRICATING SAME

(71) Applicant: Taiwan Semiconductor Manufacturing Company, LTD., Hsinchu (TW)

(72) Inventors: Tzu-Ging Lin, Kaohsiung (TW); Mei-Chun Huang, Hsinchu (TW); Yun-Chen Wu, Hsinchu (TW)

(21) Appl. No.: 18/971,198

(22) Filed: Dec. 6, 2024

(51) Int. Cl. H10D 84/83; H10D 30/00; H10D 30/01; H10D 30/62; H10D 30/67; H10D 62/10; H10D 62/13; H10D 84/01; H10D 88/00

(52) U.S. Cl. CPC H10D 84/834; H10D 30/019; H10D 30/024; H10D 30/501; H10D 30/6211; H10D 30/6735; H10D 62/121; H10D 62/149; H10D 84/013; H10D 84/0158; H10D 88/01; H10D 88/101

(57) ABSTRACT

Fabrication of three-dimensional (3D) transistors includes forming 3D transistor structures including 3D channels and source and drain (S/D) regions connected with the 3D channels. The S/D regions have convex upper surfaces. Mask material is formed on the S/D regions. At least one dielectric layer is disposed over the mask material and over the 3D transistor structures. The at least one dielectric material and the mask material are etched to open access recesses through the at least one dielectric layer accessing the S/D regions. The etching also etching the convex upper surfaces of the S/D regions to form etch-modified upper surfaces of the S/D regions. The access recesses are filled with an electrically conductive material to form S/D contacts to the etch-modified upper surfaces of the S/D regions. The etch-modified upper surfaces may have concave curvature parallel with the 3D channels, and may also have flattened or less convex transverse curvature.

### BACKGROUND

The following relates to three-dimensional transistors such as FinFETs, gate-all-around (GAA) transistors, and the like, and to methods of fabricating same.

In a FinFET, GAA transistor, or other three-dimensional (3D) transistor, parasitic capacitance between the gate metal or other gate contact (MG contact) and the source and drain metal or other source and drain contacts (MD contact) can degrade performance. Another mechanism for performance degradation is high contact resistance between the source and drain epitaxial material and the MD contact.

The following discloses certain improvements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a perspective view of a portion of an array of three-dimensional (3D) transistor structures including 3D channels and source and drain (S/D) regions connected with the 3D channels according to a nonlimiting illustrative embodiment.

FIG. 2 diagrammatically illustrates an X-cut view on Fin of a portion of a 3D transistor array according to a nonlimiting illustrative embodiment.

FIG. 3 diagrammatically illustrates an MD etch to form openings for source and drain contacts (i.e., MD contacts) according to a nonlimiting illustrative embodiment.

FIGS. 4A, 4B, and 4C diagrammatically illustrate MD contacts according to a nonlimiting illustrative embodiment.

FIGS. 5A, 5B, and 5C diagrammatically illustrate features of a 3D transistor array designed to reduce parasitic capacitance between gate metal (MG) and the MD contact metal (i.e., to reduce MG-MD parasitic capacitance) according to a nonlimiting illustrative embodiment.

FIGS. 6A and 6B diagrammatically illustrate a suitable approach for fabricating the features of the 3D transistor array of FIGS. 5A-5C.

FIGS. 7A, 7B, 7C, and 7D diagrammatically illustrate features of a 3D transistor array designed to reduce MG-MD parasitic capacitance according to a nonlimiting illustrative embodiment.

FIGS. 8A and 8B diagrammatically illustrate a suitable approach for fabricating the features of the 3D transistor array of FIGS. 7A-7C.

FIG. 9 diagrammatically illustrates an MD etch to form openings for MD contacts according to a nonlimiting illustrative embodiment.

FIG. 10 diagrammatically illustrates an MD etch according to a nonlimiting illustrative embodiment.

FIGS. 11A, 11B, 11C, and 11D diagrammatically illustrate a 3D transistor array that includes a cut-metal gate (CMG) dielectric structure according to a nonlimiting illustrative embodiment.

FIGS. 12A, 12B, and 12C diagrammatically illustrate features of a 3D transistor array that includes a CMG dielectric structure according to a nonlimiting illustrative embodiment.

FIGS. 13A, 13B, 13C, 13D, 13E, 13F, 13G, 13H, 13I, 13J, 13K, 13L, 13M, 13N, and 13O diagrammatically illustrate fabrication steps of a 3D transistor array according to a nonlimiting illustrative embodiment.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

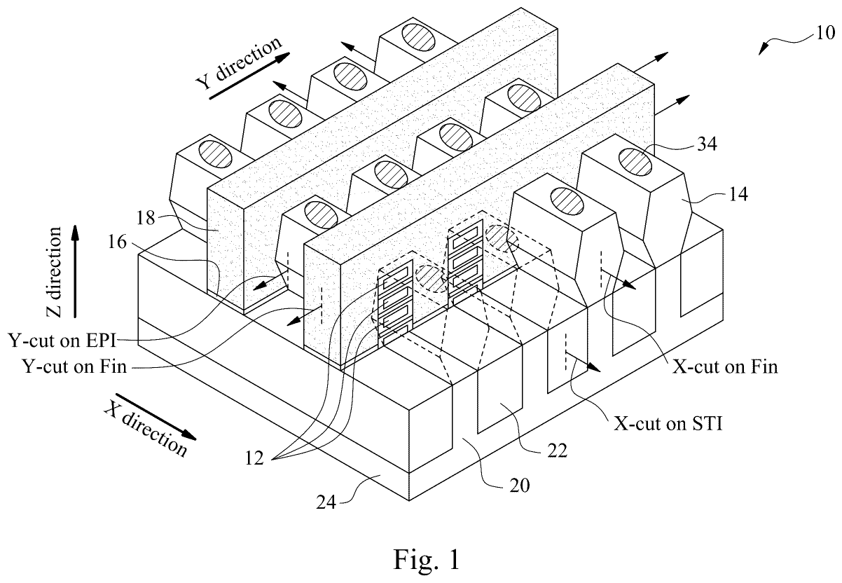

Some embodiments herein relate to methods of forming source and drain connections for a 3D transistor that includes a 3D channel, or source and drain connections for an array of 3D transistors that include 3D channels. FIG. 1 diagrammatically shows a perspective view of a portion of an array of 3D transistor structures 10 including 3D channels 12 comprising semiconductor material, and source and drain (S/D) regions 14 connected with the 3D channels 12. Each of the illustrative 3D channels 12 comprises a stack of semiconductor sheets coated with a gate dielectric 16 and surrounded by a gate 18 (also referred to herein as a metal gate, or MG, 18). This type of 3D transistor is known as a gate-all-around (GAA) transistor, and as seen in the perspective view 10 of FIG. 1 each 3D channel 12 is disposed on a fin 20, with the fins being separated by a dielectric material 22. The array of 3D transistors 10 are fabricated on a substrate 24.

In one nonlimiting illustrative example, the substrate 24 is silicon, the fins 20 are silicon fins, the insulating regions 22 are shallow trench isolation (STI) regions 22. The semiconductor sheets of the channel 12 of the nonlimiting illustrative GAA transistor may also be silicon, although other types of semiconductor material are contemplated. While GAA transistors are illustrated as nonlimiting illustrative examples, the approaches disclosed herein for reducing MD-MG parasitic capacitance without concomitant increase in contact resistance for MD contacts to the S/D regions 14 can be employed in other types of 3D transistors, such as FinFET transistors, 3D transistors employing a channel comprising a plurality of mutually parallel nanowires, or so forth. The S/D regions 14 are typically formed by epitaxial growth, e.g., epitaxial silicon growth, such that the S/D regions 14 comprise epitaxially deposited silicon, and may also be designated as EPI 14.

Without loss of generality, to facilitate description herein of geometrical and spatial arrangements, the mutually parallel 3D channels 12 are described as extending along an X-direction, and a Y-direction is transverse to (i.e., orthogonal to) the X-direction, as shown in FIG. 1, and a Z-direction is transverse to (i.e., orthogonal to) both the X-direction and the Y-direction. The “height” of a feature denotes its upper surface or extent along the Z-direction. Various cut views illustrated herein include: X-cut on Fin (i.e., the cut plane is parallel with the X-direction and Z-direction and cuts through a fin 20); X-cut on STI (i.e., the cut plane is parallel with the X-direction and Z-direction and cuts through an STI region 22); Y-cut on EPI (i.e., the cut plane is parallel with the Y-direction and Z-direction and cuts through successive epitaxial S/D regions 14 as shown in the perspective view of FIG. 1); and Y-cut on Fins (i.e., the cut plane is parallel with the Y-direction and Z-direction and cuts through successive channel 12/fin 20 structures as shown in the perspective view of FIG. 1). A plan view or top view is a view looking down on the 3D transistor array, i.e., the direction of viewing is the-Z-direction. It is to be understood that all plan views and cut views illustrated herein are diagrammatic in nature, and are not generally to scale.

The perspective view of FIG. 1 shows a hexagonal shape (i.e., cross-section in a plane parallel with the Y-and Z-directions) for the epitaxial S/D regions 14, which corresponds to epitaxial deposition of silicon along principle crystalline planes outward from the top of the fin 20 upward (i.e., in the Z-direction) and sideways. However, the shape of the epitaxial S/D regions 14 depends on various factors such as the epitaxial growth conditions (e.g., silicon flux, growth temperature).

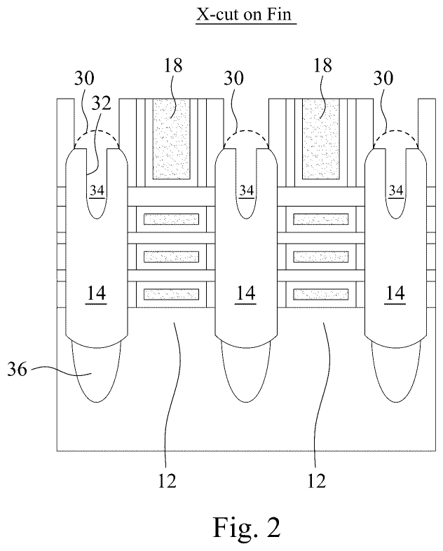

With reference to FIG. 2 which shows an X-cut view on Fin, under many epitaxial growth conditions the epitaxial S/D regions 14 have more rounded or elliptical cross-sections. As diagrammatically shown in FIG. 2, a consequence of this is that the epitaxial S/D regions 14 have convex upper surfaces 30 (diagrammatically shown in FIG. 2 by a dashed line). In some embodiments disclosed herein, these convex upper surfaces 30 of the epitaxial S/D regions 14 are leveraged to facilitate modification of the upper surfaces by an etching step during the source and drain contact fabrication process to produce etch-modified upper surfaces 32 of the S/D regions 14. In the nonlimiting illustrative example of FIG. 2, the etch-modified upper surfaces 32 comprise a concave upper surface portion 32 of each S/D region 14 after the etching. The concave upper surface portion 32 has concave curvature along the X-direction parallel with the 3D channels 12, and the concave upper surface portion 32 partially surrounds an upper cavity 34 formed in the S/D region 14 by the etching. Subsequent formation of the source and drain contacts by deposition of electrically conductive material (not shown in FIG. 2) fills the upper cavities 34 formed in the S/D regions 14 with the electrically conductive material. This advantageously provides low contact resistance due to the increased conformal contact area between the electrically conductive material and the concave upper surface portion 32 of each S/D region 14. FIG. 2 also illustrates an optional isolation dielectric structure 36 disposed under the epitaxial source/drain regions 14 to provide an isolation of the epitaxial source/drain regions 14 from the fin 20 and substrate 24.

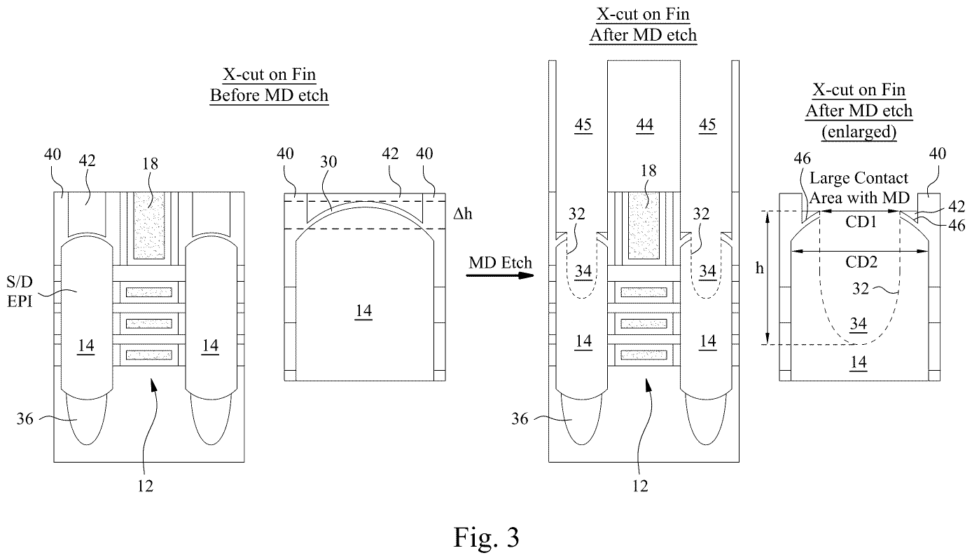

With reference to FIG. 3, formation of the concave upper surface portions 32 of the S/D regions 14 by etching is described. The etching is performed after deposition of at least one dielectric layer 44, to access the S/D regions 14 to enable electrically conductive material to be deposited to form the source and drain metal or other source and drain contacts (MD contacts), and hence the etch is also referred to herein as an MD etch. The left side of FIG. 3 shows an X-cut on Fin before the MD etch (and before deposition of the at least one dielectric layer). As seen, the S/D regions 14 have the previously described convex upper surfaces 30. Without loss of generality, the convex upper surfaces 30 of the S/D regions 14 have a height designated Δh. During processing, dielectric spacers 40 (i.e., filler dielectric material 40) may be formed around the upper portion or above the S/D regions 14, and mask material 42 is formed on the S/D regions. In one nonlimiting illustrative example, the mask material 42 is silicon nitride (SiN). In other nonlimiting illustrative examples, the mask material may be a dielectric material that is doped to provide desired etching characteristics for the mask material during the MD etch. Various approaches for the formation are described later herein.

As seen in the after-MD etch X-cut on Fin views shown on the right-side of FIG. 3, at least one dielectric layer 44 is disposed over the mask material 42 and the 3D transistor structures (e.g., including the 3D channels 12 and S/D regions 14). The at least one dielectric layer 44 may also be referred to as an interlayer dielectric (ILD). The at least one dielectric layer 44 may comprise (by way of some nonlimiting illustrative examples) silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof.

Access recesses 45 accessing the S/D regions 14 (and more particularly accessing the convex upper surfaces 30 of the S/D regions 14) are formed in the at least one dielectric layer 44 by the MD etch. The MD etch also etches the mask material 42, and continues etching into the convex upper surfaces 30 of the S/D regions 14. The MD etch may, for example, be a high density (HD) plasma etch. In some embodiments, the MD etch has a faster etch rate for the S/D regions 14 than for the mask material 42 (e.g., a faster etch rate for the silicon of the illustrative epitaxial silicon S/D regions 14 than for the illustrative silicon nitride mask material 42). As the MD etch forming the access recesses 45 penetrates through the mask material 42, it first reaches the tops of the convex upper surfaces 30 of the S/D regions 14. At that point, the MD etching starts etching the central region of the convex upper surfaces 30 of the S/D regions 14. The etching of the convex upper surfaces 30 of the S/D regions 14 proceeds at a faster rate than the etching of the mask material 42 still present at the periphery of the convex upper surfaces 30 of the S/D regions 14. This combination of conditions results in the MD etching proceeding more rapidly in the central region of the S/D regions 14 than at the periphery, which results (as shown in the X-cut on Fin after MD etch drawing on the right-hand side of FIG. 3) in formation of the upper cavity 34 in the S/D region 14, which is bounded by (i.e., partially surrounded by) the concave upper surface portion 32 of the S/D region 14.

As best seen in the enlarged view of the X-cut on Fin after MD etch shown rightmost in FIG. 3, in this example the MD etch terminates with some residual mask material 42 around the periphery of the S/D region 14, which protects a remaining convex upper surface portion 46 of the S/D region 14 after the MD etch. As a consequence of this, the upper cavity 34 formed in the S/D region 14 by the MD etching has a smaller lateral dimension CD1 along the X-direction (which is parallel with the 3D channels, see FIG. 1) than a lateral dimension CD2 of the S/D regions along the direction parallel with the 3D channels. This can be beneficial as it provides additional spacing between the gate 18 and the electrically conductive material that subsequently fills the upper cavity 34 to form S/D contact to the S/D region 14.

As further labeled in the enlarged view of the X-cut on Fin after MD etch shown rightmost in FIG. 3, in this example the MD etch produces the upper cavity 34 with a depth h. In some embodiments, the upper cavities 34 formed in the S/D regions 14 by the MD etching have depth h which is a monotonically increasing function of the height Δh of the convex upper surfaces 30 of the S/D regions 14 prior to the etching. This is a consequence of a higher value for height Δh of the convex upper surfaces 30 leading to the MD etch encountering the tops of the convex upper surfaces 30 sooner, at which point the faster etching of the material of the S/D regions 14 commences.

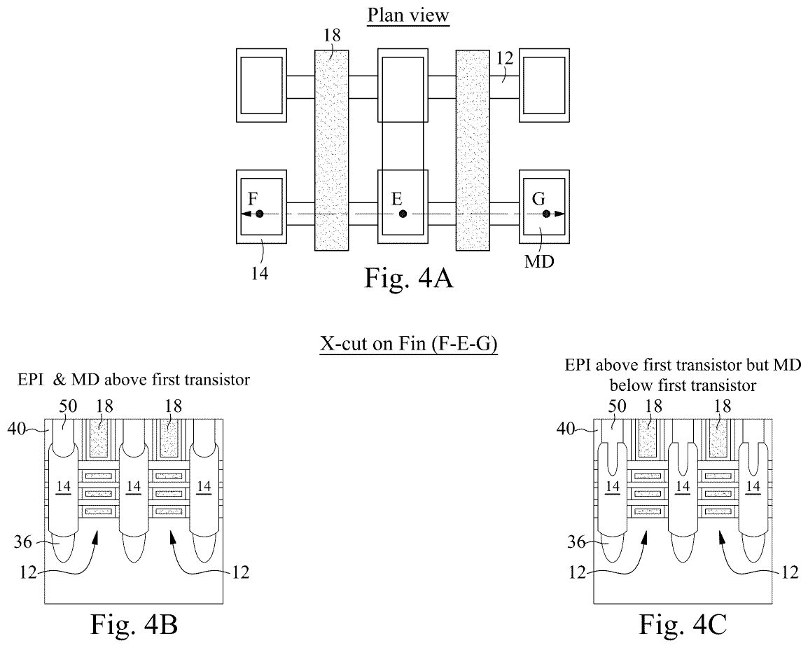

With reference to FIGS. 4A, 4B, and 4C, the detailed shape of the upper cavity 34, and consequently the detailed shape of the portion of electrically conductive material that subsequently fills the upper cavity 34 to form S/D contact to the S/D region 14, depends on factors such as the initial height Δh and/or detailed convex curvature of the convex upper surface 30 of the epitaxial S/D region 14, the difference between the faster etch rate of the MD etching of the material of the S/D region 14 compared with the slower etch rate of the MD etching of the material of the hard mask 42, the etch time of the MD etch, and so forth. FIG. 4A diagrammatically shows a top view indicating an X-cut on a fin, with letters “F”, “E”, and “G” indicating points along the X-direction. FIGS. 4B and 4C show two examples, presented as X-cuts on the Fin (per FIG. 4A) showing the structure after the MD etch and subsequent deposition of electrically conductive material to fill the upper cavities 34 to form S/D contacts to respective S/D regions 14. Note that in FIGS. 4B and 4C the at least one dielectric layer 44 is omitted. In practice, most of the thickness of the at least one dielectric layer 44 may be removed by chemical mechanical polishing (CMP) after the S/D contacts are formed.

In the example of FIG. 4B, S/D contacts 50 fill the upper cavities 34 each of which has critical dimension CD1 along the X-direction (see FIG. 3) that is close to the critical dimension CD2 along the X-direction of the S/D region 14. As seen in the example of FIG. 4B, the epitaxial S/D regions 14 have height (i.e., along the Z-direction indicated in FIG. 1) that is above the top of the channel 12, and the bottoms of the S/D contacts 50 are also above the top of the channel 12. This arrangement can advantageously reduce MG-MD parasitic capacitance (that is, the parasitic capacitance between the gate 18 and S/D contacts 50), by increasing the distance between the gate 18 and S/D contacts 50.

In the example of FIG. 4C, by contrast, S/D contacts 50 shown in FIG. 4C fill the upper cavities 34 each of which has critical dimension CD1 along the X-direction (see FIG. 3) that is smaller than the critical dimension CD2 along the X-direction of the S/D region 14. As seen in the example of FIG. 4C, the epitaxial S/D regions 14 have height that is above the top of the channel 12, but the bottoms of the S/D contacts 50 of FIG. 4C are below the top of the channel 12. This arrangement can advantageously reduce contact resistance of the S/D contacts 50 of FIG. 4C, by positioning the S/D contacts 50 of FIG. 4C closer to the channel 12.

It will be appreciated that the design of the S/D contacts can be optimized with respect to both minimizing MG-MD parasitic capacitance and minimizing S/D contact resistance by empirically adjusting process parameters such as the shape of the convex upper surface 30 of the epitaxial S/D region 14 (which is controllable by adjustment of epitaxial silicon deposition parameters such as deposition rate, deposition temperature, and/or so forth), the etch rate and total etch time of the MD etching, and so forth, using cross-section transmission electron microscopy (TEM), scanning electron microscopy (SEM), optical microscopy, or other characterization techniques to assess the geometry of the S/D contacts, and/or using electrical characterization techniques to directly measure the MG-MD parasitic capacitance and minimizing S/D contact resistance.

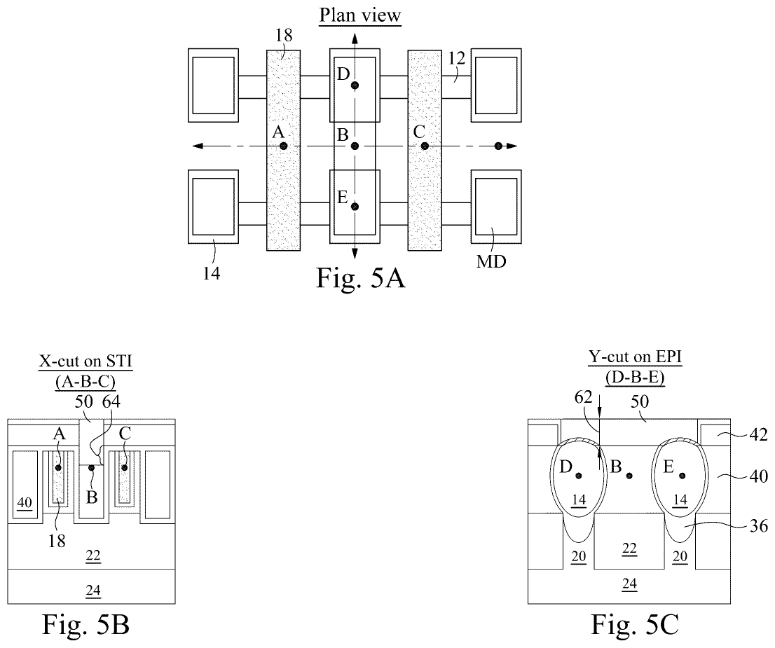

FIG. 5A diagrammatically shows a top view indicating an X-cut on STI, with letters “A”, “B”, and “C” indicating points along the X-direction, and a Y-cut on EPI, with letters “D”, “B”, and “E” indicating points along the Y-direction. FIGS. 5B and 5C show the X-cut on STI (along the line A-B-C) and the Y-cut on EPI (along the line D-B-E), respectively. In this example, MD metallization 50 (which also forms the S/D contacts 50 of FIG. 4B or 4C) is at a shallow depth 62 which advantageously provides a low MG-MD parasitic capacitance. In the example of FIG. 5B, for example, an overlap 64 between the MD metallization 50 and the gate 18 in the region around point “B” is small (or, in some embodiments, there is zero overlap), thus providing a small MD-MG parasitic capacitance. It will be appreciated that the embodiment of FIGS. 5A, 5B, and 5C may optionally be showing different cut views of the same embodiment as FIG. 4B or FIG. 4C.

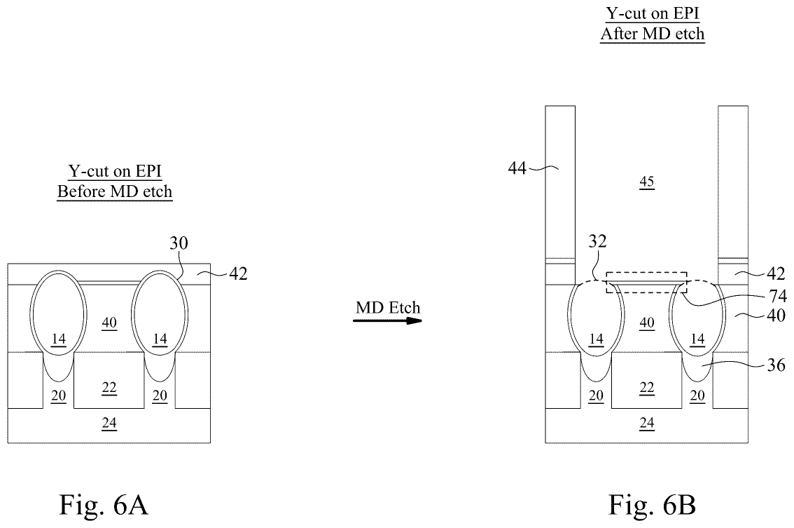

FIGS. 6A and 6B show how the MD etch forms the structures shown in FIGS. 5B and 5C. The before-MD etch Y-cut on EPI view of FIG. 6A shows the S/D regions 14, the filler dielectric material 40 disposed between adjacent S/D regions 14 which are adjacent along the Y-direction transverse to the 3D channels 12, and the mask material 42 which is formed both on the S/D regions 14 and on the filler dielectric material 40. The after-MD etch Y-cut on EPI view of FIG. 6B shows the deposited at least one dielectric layer 44 and the access recess formed by the MD etch in the at least one dielectric layer 44 and also etching through the mask material 42 to access the tops of the S/D regions 14. As seen in FIG. 6B, the MD etch leaves a portion of the filler dielectric layer 40 disposed between the adjacent S/D regions, so that in some embodiments there is a small (or no) recess in the dielectric filler material 40 between the adjacent S/D regions 14 after the MD etch. This small or eliminated recess advantageously provides a small MG-MD parasitic capacitance.

While the upper surface portions of the S/D regions 14 after the MD etch have concave curvature in the X-direction in some embodiments (see, e.g., FIG. 3), in the transverse Y-direction shown in FIG. 6B the upper surface portions 30 of the S/D regions 14 are flattened compared with a convexity in the Y-direction of the convex upper surfaces 30 of the S/D regions 14 prior to the MD etch (shown in FIG. 6A). Hence, in some embodiments the concave upper surface portions 32 of the S/D regions 14 have a saddle-shape, with concave curvature in the X-direction and flat or convex curvature in the orthogonal Y-direction.

Further describing the processing depicted in FIGS. 6A and 6B, the filler dielectric material 40 does not fully cover the S/D regions 14, so that the tops of the S/D regions 14 are above the filler dielectric material 40. The mask material 42 (e.g., a silicon nitride layer) is disposed on the filler dielectric material 40, as shown in FIG. 6A, and also on the convex upper surfaces 70 of the S/D regions 14 which are not covered by the filler dielectric material 40. As previously described with reference to FIG. 3, during the MD etch the epitaxial S/D region 14 etches faster than the mask material, and as the MD etch continues it initially etches the peaks of the convex upper surfaces 30 of the S/D regions 14. In this example, the MD etch is short enough, and/or the convex upper surfaces 30 of the S/D regions 14 penetrate a short enough distance into the mask material 42, so that the faster MD etching of the S/D regions 14 flattens the upper surfaces 30 to produce etch-modified upper surfaces 32 of the S/D regions 14 (shown in FIG. 6B, depicting post-MD etch) which are flattened in the Y-direction (i.e., transverse to the 3D channels 12) compared with the convexity of the upper surfaces 30 in the Y-direction prior to the etching. As labeled by box 74 in FIG. 6B, this results in the portion of the filler dielectric material 40 located between the adjacent S/D regions 14 (i.e., adjacent along the Y-direction) having no recess. Thus, when the access recess 45 formed by the MD etch is filled with electrically conductive material to form the S/D contacts, the lack of a recess in the portion 74 of the filler dielectric material 40 between adjacent S/D regions 14 advantageously reduces parasitic MD-MG capacitance.

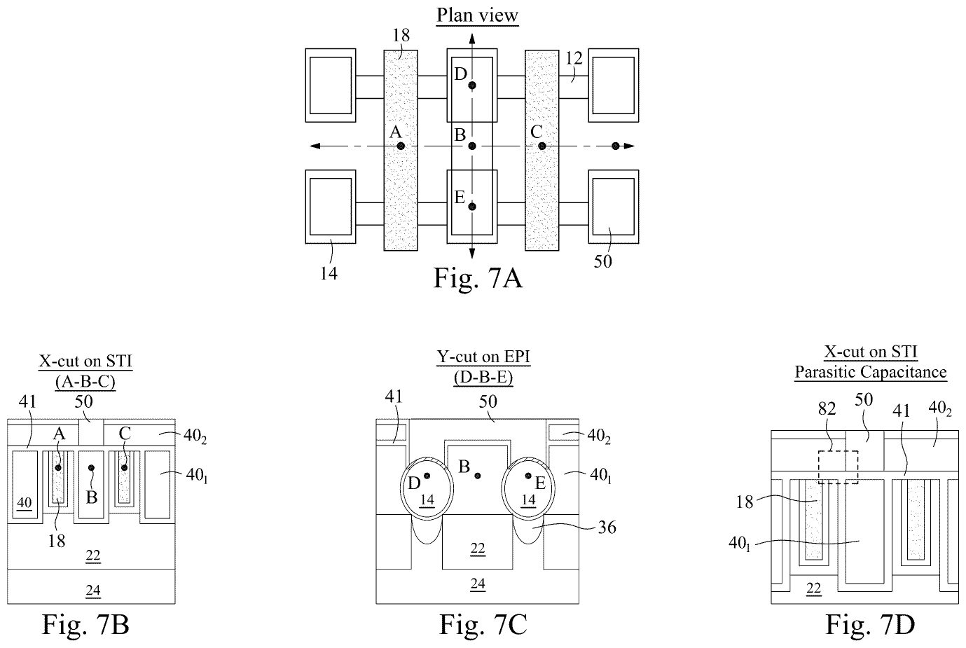

With reference to FIGS. 7A, 7B, 7C, and 7D, another disclosed approach is diagrammatically shown for advantageously reducing parasitic MD-MG capacitance. As diagrammatically shown in the plan view of FIG. 7A, this embodiment is illustrated using the same cut lines as are shown in FIG. 5A. FIG. 7B shows the X-cut on STI (along the line A-B-C) and FIG. 7C the Y-cut on EPI (along the line D-B-E), respectively. FIG. 7D shows an enlarged view of a portion of the X-cut on STI. In this embodiment, the filler dielectric material 40 includes a first dielectric layer 40₁, an etch stop layer 41 disposed over the first dielectric layer 40₁, and a second dielectric layer 40₂ disposed on the etch stop layer 41. The first dielectric layer 40₁ has a height greater than or equal to a maximum height of the gates 18. The etch stop layer 41 can be used to provide a definite stop for the MD etch to ensure that the portion of the filler dielectric material 40₁ located between the adjacent S/D regions 14 (i.e., adjacent along the Y-direction) has no recess, thereby ensuring that the metallization 50 of the S/D contacts (also referred to herein as the MD metallization 50) is at or above the height of the gates 18. As highlighted in FIG. 7D, there is zero overlap 82 between the electrically conductive material of the S/D contacts (i.e., MD contacts) 50 and the tops of the gates 18, thus advantageously reducing parasitic MD-MG capacitance.

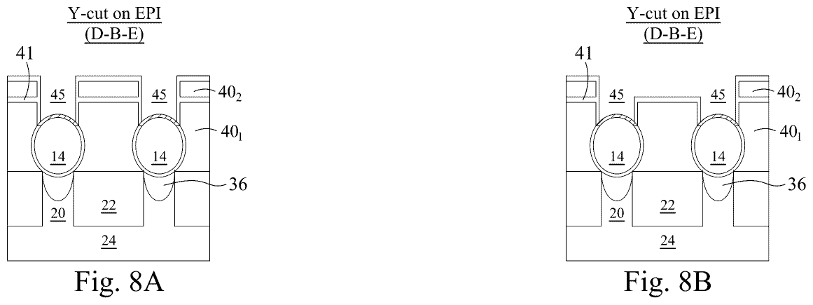

With reference to FIGS. 8A and 8B, a suitable approach for forming the MD contacts of FIGS. 7B, 7C, and 7D is shown by way of Y-cuts (D-B-E) on EPI. In this illustrative approach, the first and second dielectric layers 40₁ and 40₂ are deposited with the etch stop layer 41 interposed between the first and second dielectric layers 40₁ and 40₂. After a first patterned etch as shown in FIG. 8A, recesses 86 are formed through both first and second dielectric layers 40₁ and 40₂ to access the S/D regions 14. The first patterned etch uses an etchant that does etch the etch stop layer 41. Thereafter, a second patterned etch is performed to remove the portion of the second dielectric layer 40₂ disposed between adjacent S/D regions 14 along the Y-direction. This etch utilizes an etchant that does not etch the etch stop layer 41, so that the etch stop layer 41 is operative to stop the second patterned etch at the top of the first dielectric layer 40₁ and leave a portion of the first dielectric layer 40₁ disposed between adjacent S/D regions 14 along the Y-direction, which in this example has a height greater than the maximum height of the convex upper surfaces of the S/D regions 14.

It is to be appreciated that the approach of FIGS. 8A and 8B is merely one nonlimiting illustrative way of forming the structure of FIGS. 7B, 7C, and 7D. For example, another approach (not shown) could deposit and pattern only the first dielectric layer, followed by patterned deposition of the second dielectric layer over the selected portion of the first dielectric layer.

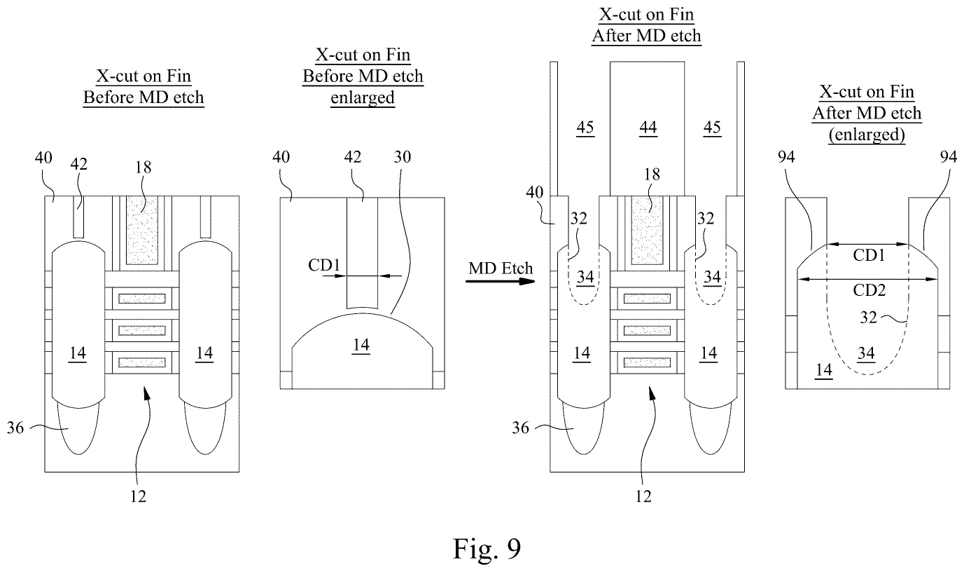

With reference to FIG. 9, a variant embodiment to that of FIG. 3 is shown. As with FIG. 3, in the embodiment of FIG. 9 is illustrated by X-cuts on Fin before and after the MD etch. As seen in the before MD etch state shown on the left side of FIG. 9, mask material 42 is disposed on the S/D regions 14 (surrounded by filler spacers 40). The at least one dielectric layer 44 is deposited, and in the MD etch access openings 45 are etched through the at least one dielectric layer 44, as seen in the after-MD etch on the right side of FIG. 9. The MD etch also removes the mask material 42 and etches into the convex upper surfaces of the S/D regions 14 to form the upper cavities 34 delineated by the concave upper surface portions 32 of the etched S/D regions 14. In the embodiment of FIG. 9, the mask material 42 is of smaller lateral dimension CD1 along the X-direction (which is parallel with the 3D channels, see FIG. 1) compared with the corresponding dimension CD1 of the embodiment of FIG. 3. As the etch penetrates through the mask material 42, it first reaches the tops of the convex upper surfaces 30 of the S/D regions 14. At that point, the MD etching starts etching the central region of the convex upper surfaces 30 of the S/D regions 14. The etching of the convex upper surfaces 30 of the S/D regions 14 proceeds at a faster rate than the etching of the mask material 42 still present at the periphery of the convex upper surfaces 30 of the S/D regions 14. This combination of conditions results in the MD etching proceeding more rapidly in the central region of the S/D regions 14 than at the periphery, which results (as shown in the X-cut on Fin after MD etch drawing on the right-hand side of FIG. 3) in formation of the upper cavity 34 in the S/D region 14, which is bounded by (i.e., partially surrounded by) the concave upper surface portion 32 of the S/D region 14. In the embodiment of FIG. 9, the narrower critical dimension CD1 of the mask material 42 when compared with the embodiment of FIG. 3 results in the upper cavity 34 in the S/D region 14 also having this narrower CD1, as seen in the righthand (after MD etch) X-cut on Fin shown in FIG. 9.

Furthermore, in the embodiment of FIG. 9 the mask material 42 is completely removed by the MD etch. By comparison, in the embodiment of FIG. 3 portions of the mask material 42 at the peripheries of the S/D regions remain after the MD etch, as best seen in the rightmost X-cut on Fin shown in FIG. 3. In the embodiment of FIG. 3, this residual mask material 42 protects remaining convex upper surface portions 46 of the S/D region 14 after the MD etch. By contrast, in the embodiment of FIG. 9 corresponding remaining convex upper surface portions 46 of the S/D region 14 after the MD etch 94 (best seen in the rightmost after-MD etch X-cut on Fin shown in the FIG. 9) are maintained due to the narrower CD1 of the mask material 42 in the embodiment of FIG. 9 compared with the embodiment of FIG. 3. The approach of FIG. 9 provides highly controllable lateral dimension for the critical dimension CD1 of the upper cavity 34 in the S/D region 14 and for the remaining convex upper surface portions 46, as these dimensions are primarily controlled by the dimension of the opening formed in the at least one dielectric layer 40 by photolithographic processing. As with the embodiment of FIG. 3, in the embodiment of FIG. 9 the upper cavity 34 formed in the S/D region 14 by the MD etching has the smaller lateral dimension CD1 along the X-direction (which is parallel with the 3D channels, see FIG. 1) than a lateral dimension CD2 of the S/D regions along the direction parallel with the 3D channels. This again provides the benefits of small contact resistance due to the increased S/D contact area provided by the concave upper surface portion 32 of the S/D region 14, and small MD-MG parasitic capacitance due to increased spacing of the gate 18 from the electrically conductive material that subsequently fills the upper cavity 34 to form S/D contact to the S/D region 14.

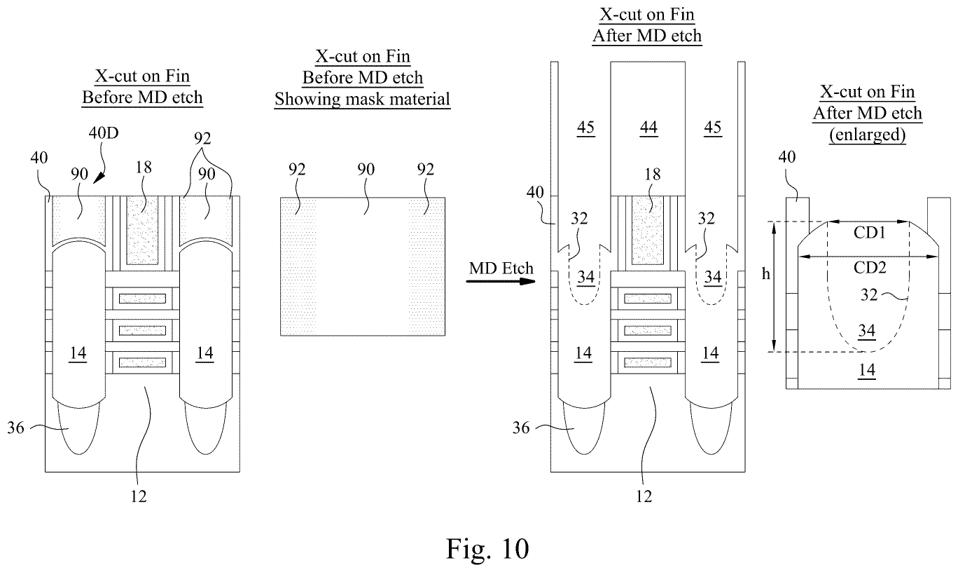

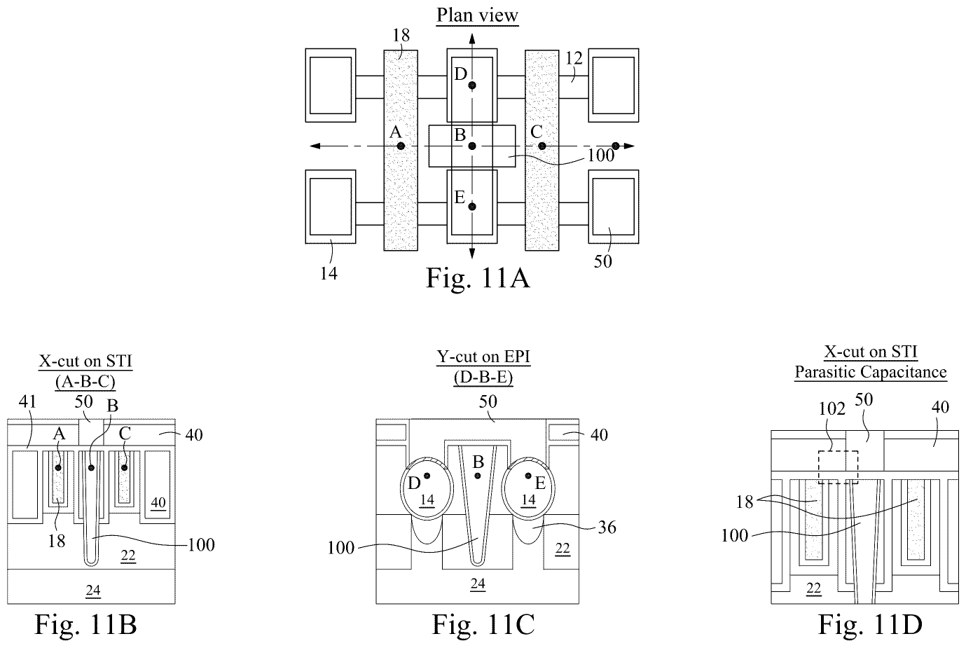

With reference to FIG. 10, in another embodiment, a different approach is described for forming concave upper surface portions 32 of S/D regions 14 after the MD etching which partially surround upper cavities 34. As in the embodiments of FIGS. 3 and 9, the embodiment of FIG. 10 is illustrated by X-cuts on Fin before and after the MD etch. In the embodiment of FIG. 10, the mask material 42 comprises a masking dielectric material 90 disposed on the S/D regions 14, for which an outer or peripheral portion 92 of the masking dielectric material 90 is doped with a dopant that is effective to reduce an etch rate (i.e., slow the etching) of the MD etch for the peripheral doped outer portion 92 of the masking dielectric material 90. In some nonlimiting illustrative examples, the masking dielectric material 90 may be silicon oxide, silicon nitride, silicon oxynitride, PSG, BPSG, SOG, FSG, SiCOH, polyimide, or so forth, and the dopant may comprise boron applied by dopant diffusion. In some nonlimiting illustrative examples, the masking dielectric material 90 may be the same as the material of the at least one dielectric layer 44. Due to the slower etching of the peripheral doped region 92, the MD etch is faster in the central portion of the masking dielectric material 90 so that the in-progress etching through the masking dielectric material 90 will be concave, and this will propagate into the etching of the S/D regions 14, thereby forming the concave upper surface portions 32 of S/D regions 14 after the MD etching which partially surround upper cavities 34.

As previously discussed with reference to FIGS. 7B, 7C, 7D and 8A and 8B, ensuring that the portion of the filler dielectric material 40 located between the adjacent S/D regions 14 (i.e., adjacent along the Y-direction) has no recess provides zero overlap between the electrically conductive material between the adjacent S/D regions and the tops of the gates 18, which advantageously reduces parasitic MD-MG capacitance.

In the following, an approach is described which uses a cut-metal gate (CMG) dielectric structure to ensure no overlap between the electrically conductive S/D contact material between the adjacent S/D regions and the tops of the gates. CMG dielectric structures are used in 3D transistor arrays to introduce cuts (i.e., electrical breaks) along a gate line to provide electrical isolation where desired to implement a particular integrated circuit (IC) design. The CMG dielectric structure comprises a strip of dielectric material oriented parallel with the X-direction (i.e., parallel with the 3D channels 12) that cuts through a gate line 18 running along the Y-direction. To provide complete isolation (i.e., a complete gate cut), the CMG dielectric structure extends vertically to or above the height of the gate line.

With reference now to FIGS. 11A, 11B, 11C, and 11D, an example is diagrammatically shown using a CMG dielectric structure 100 to ensure no overlap between the electrically conductive material forming the S/D contacts (i.e., MD contacts) 50 between the adjacent S/D regions 14 and the tops of the gates 18. FIG. 11A shows a plan view indicating the location of the CMG dielectric structure 100, and also showing locations of an X-cut on STI (through indicated points A-B-C) and a Y-cut on EPI (through indicated points D-B-E). FIG. 11B diagrammatically depicts the X-cut on STI, and FIG. 11C diagrammatically depicts the Y-cut on EPI.

As previously noted, to provide complete isolation (i.e., a complete gate cut), the CMG dielectric structure extends vertically (i.e., in the Z-direction) to a height that is equal to or above the height of the gate lines 18. Hence, as seen in FIGS. 11B and 11C, the CMG dielectric structure 100 provides an etch stop for the MD etch to ensure that there is no overlap between the electrically conductive material of the MD contacts 50 between the adjacent S/D regions 14 and the tops of the gates 18. This lack of overlap advantageously reduces parasitic MD-MG capacitance. FIG. 11D diagrammatically depicts an enlarged view of the X-cut on STI indicating a region 102 with zero overlap between the electrically conductive material of the MD contacts 50 between the adjacent S/D regions 14 and the tops of the gates 18.

As seen in FIG. 11A, while the dielectric structure 100 is referred to herein as a CMG dielectric structure 100, in the embodiment of FIG. 11A it does not actually introduce a cut (i.e., electrical break) along either of the illustrated gate lines 18. It is however referred to herein as a CMG dielectric structure 100 because it is fabricated using the same processing that is used to form CMG dielectric structures that cut gate lines. Put another way, the CMG dielectric structure 100 can be fabricated together with CMG dielectric structures that cut gate lines. For example, this can be done by modifying the mask used to form the CMG isolation structure trench, with the subsequent CMG dielectric structure fabrication process including depositing the dielectric material (e.g., silicon dioxide, silicon nitride, silicon oxynitride, an Si-O-C-N dielectric, or so forth) to fill the trench and performing CMP to remove excess dielectric material and planarize the surface. Hence, implementation of the CMG dielectric structure 100 advantageously does not entail additional processing steps.

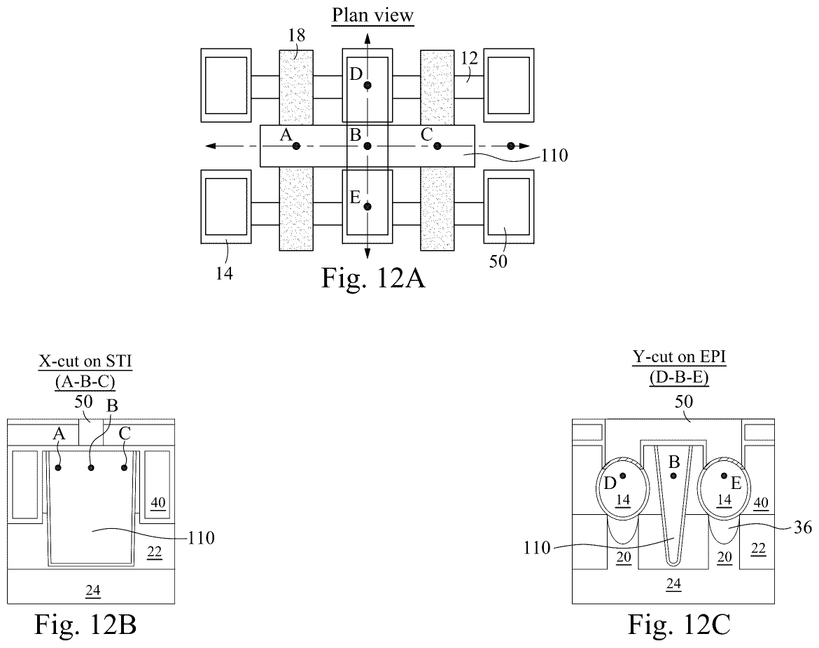

With reference to FIGS. 12A, 12B, and 12C, another embodiment is shown which again uses a CMG dielectric structure 110 to ensure no overlap between the electrically conductive material of the MD contacts 50 between the adjacent S/D regions 14 and the tops of the gates 18. FIG. 12A shows a plan view indicating the location of the CMG dielectric structure 110, and also showing locations of an X-cut on STI (through indicated points A-B-C) and a Y-cut on EPI (through indicated points D-B-E). FIG. 11B diagrammatically depicts the X-cut on STI, and FIG. 11C diagrammatically depicts the Y-cut on EPI. Unlike the embodiment of FIG. 11A, in the embodiment of FIG. 12A the CMG dielectric structure 110 cuts through the illustrated gate lines 18. Thus, the CMG dielectric structure 110 performs dual functions: cutting gate lines, which is the usual function of a CMG dielectric structure; and ensuring no overlap between the electrically conductive material of the MD contacts 50 between the adjacent S/D regions 14 and the tops of the gates 18. This is advantageously accomplished without modifying the fabrication workflow other than modifying the CMG dielectric structure trench mask.

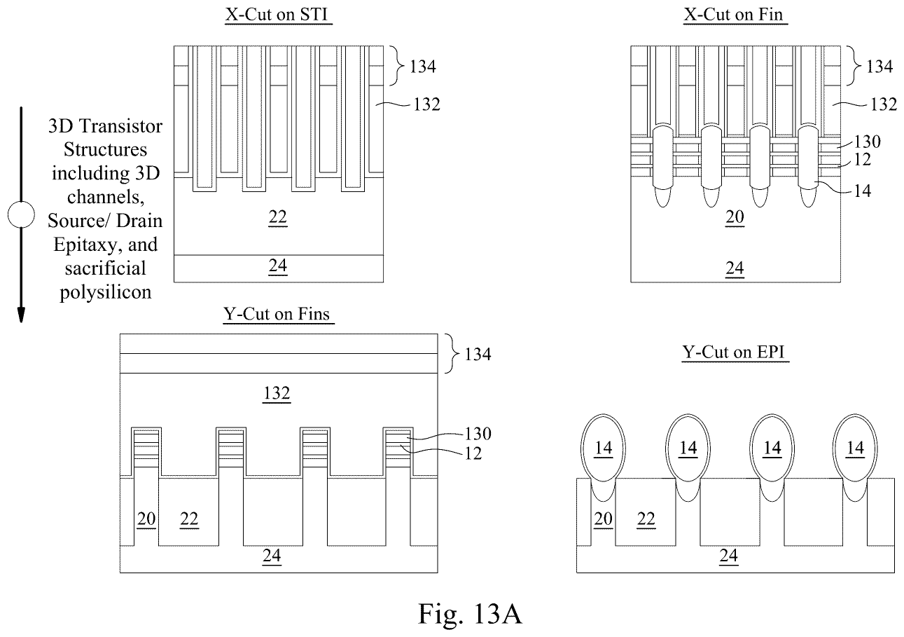

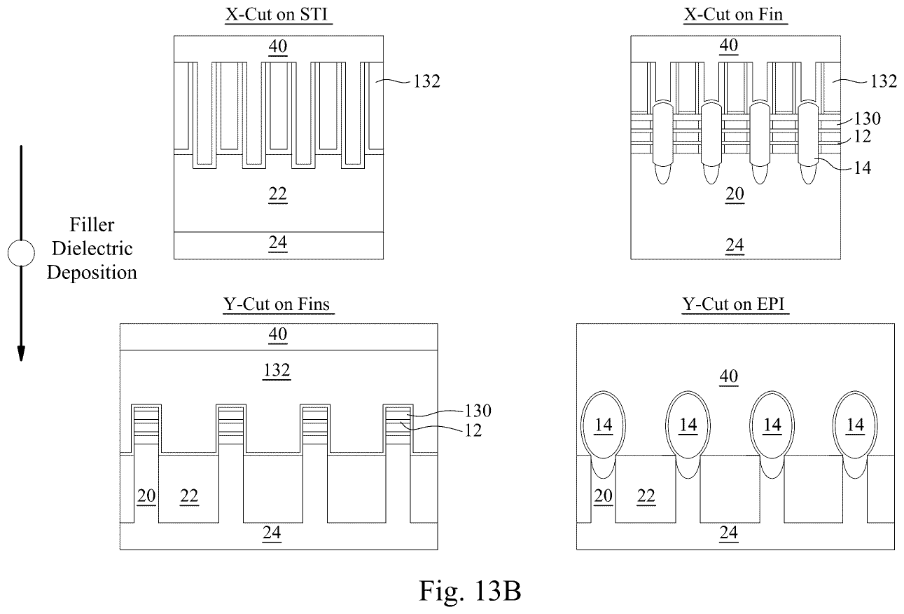

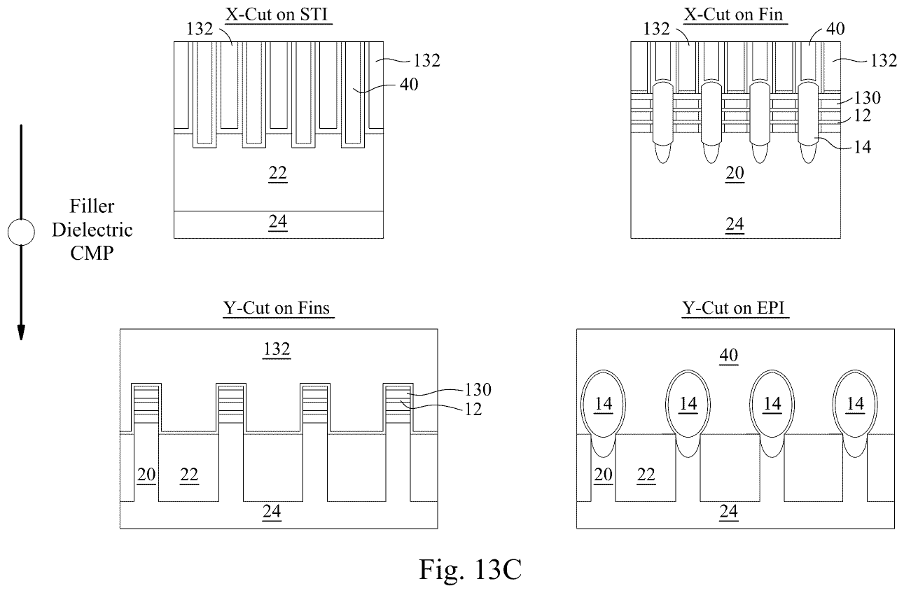

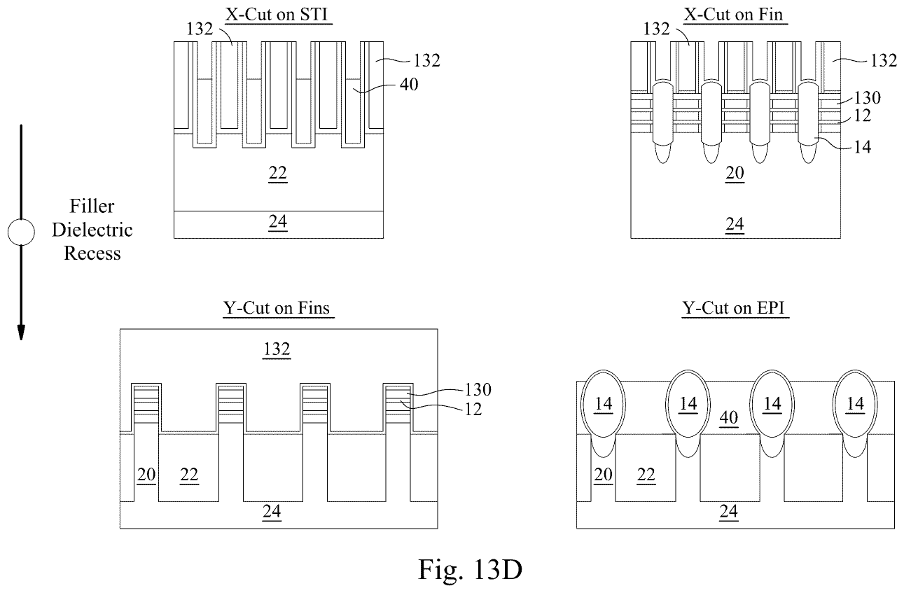

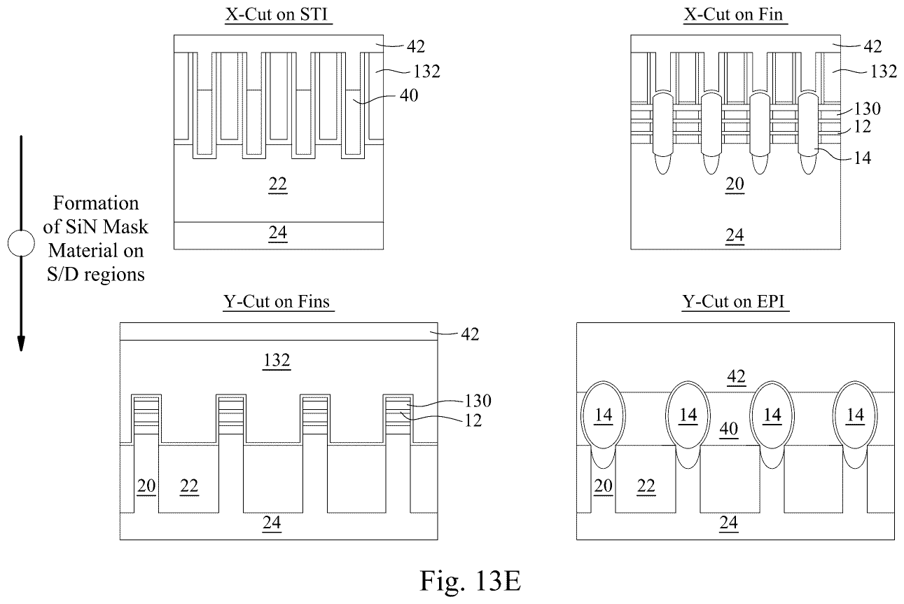

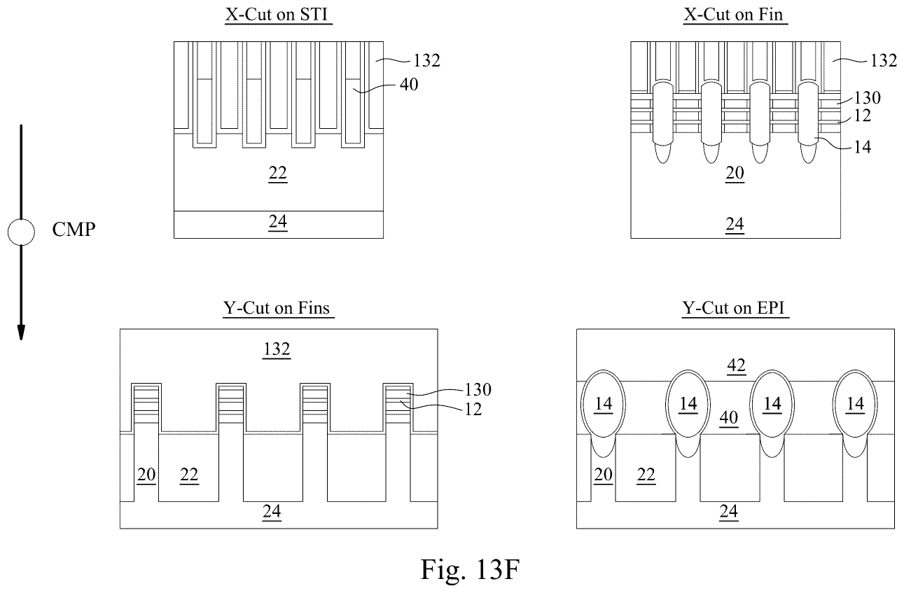

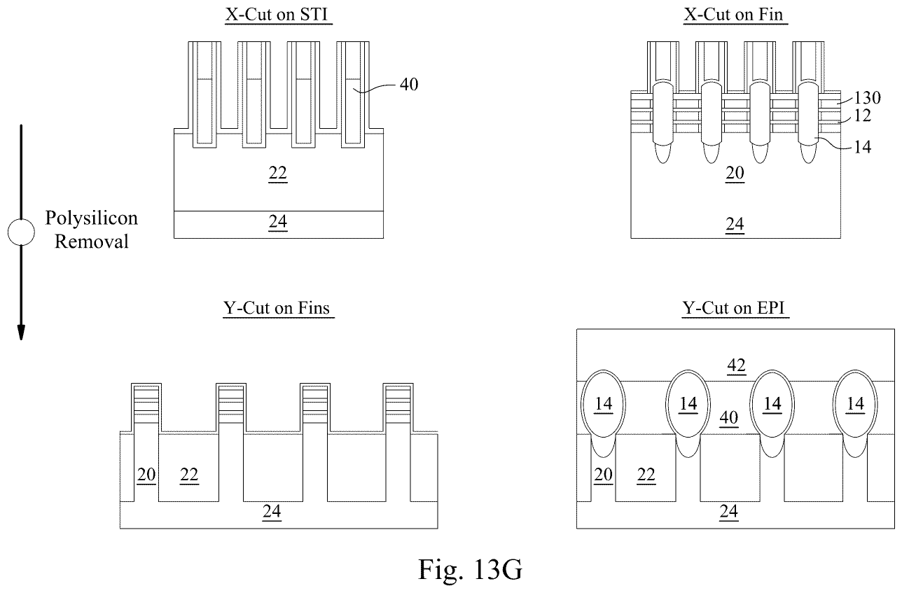

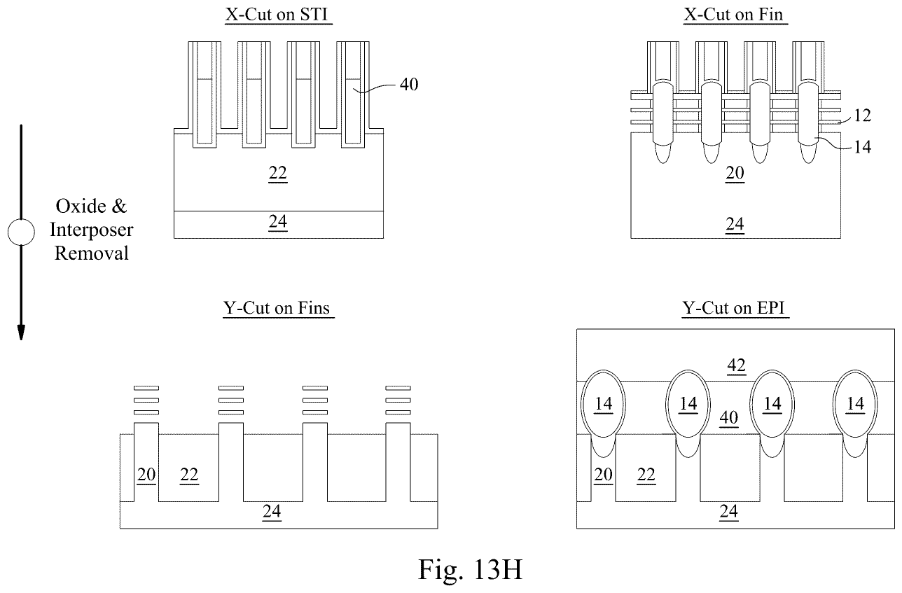

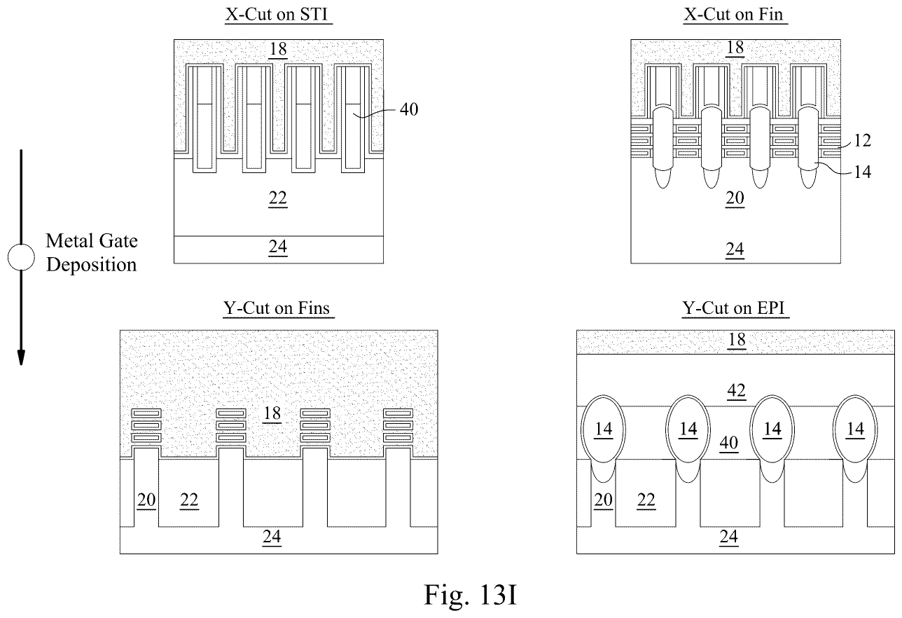

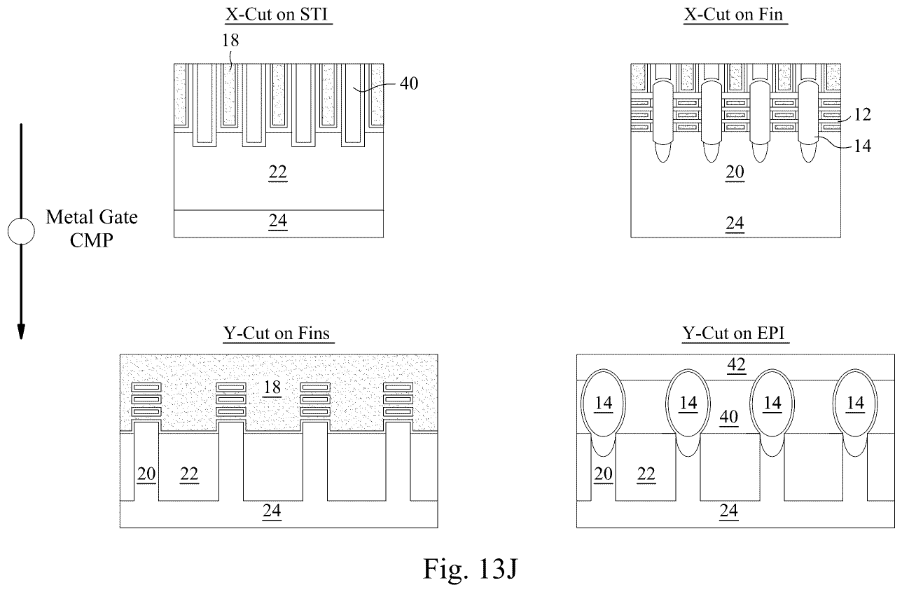

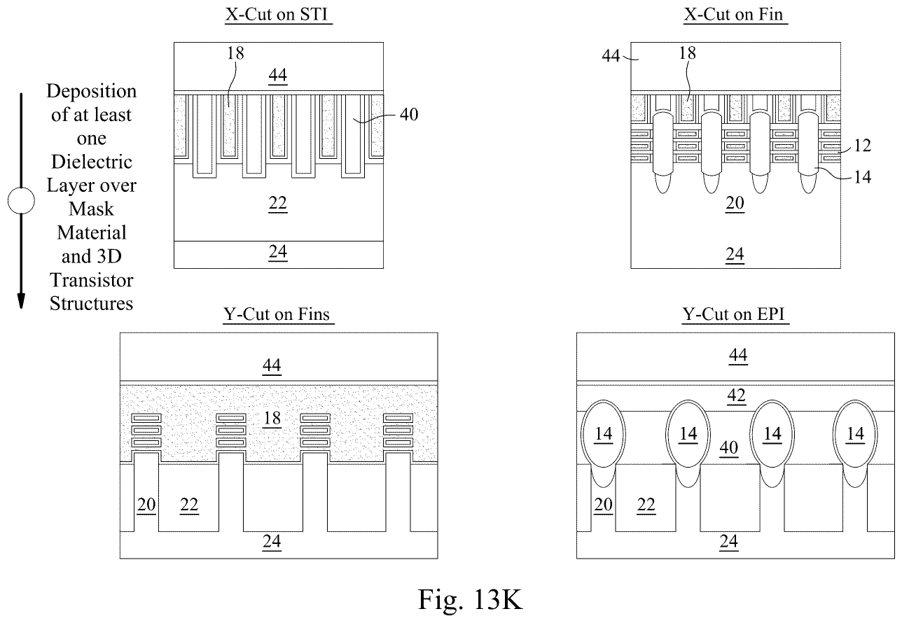

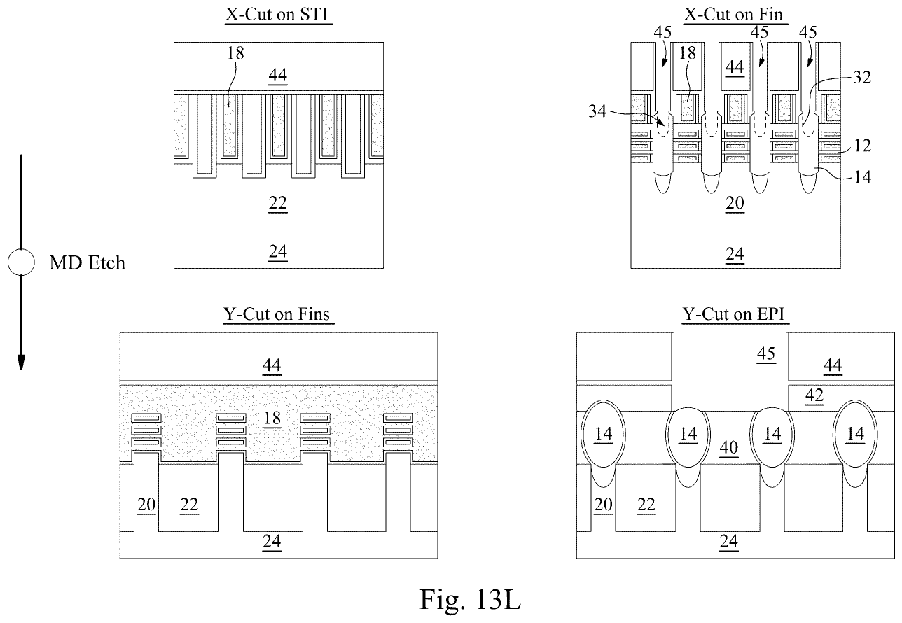

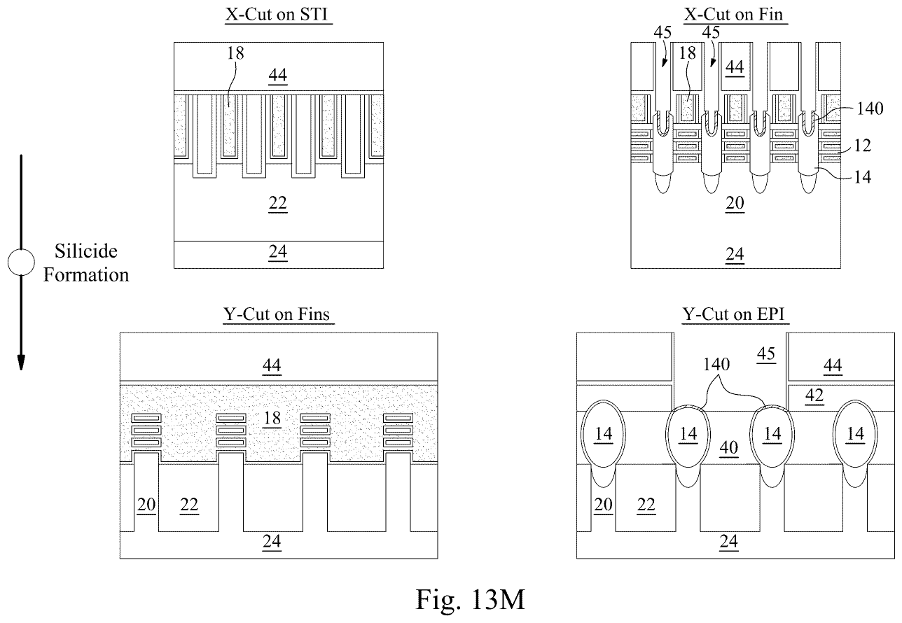

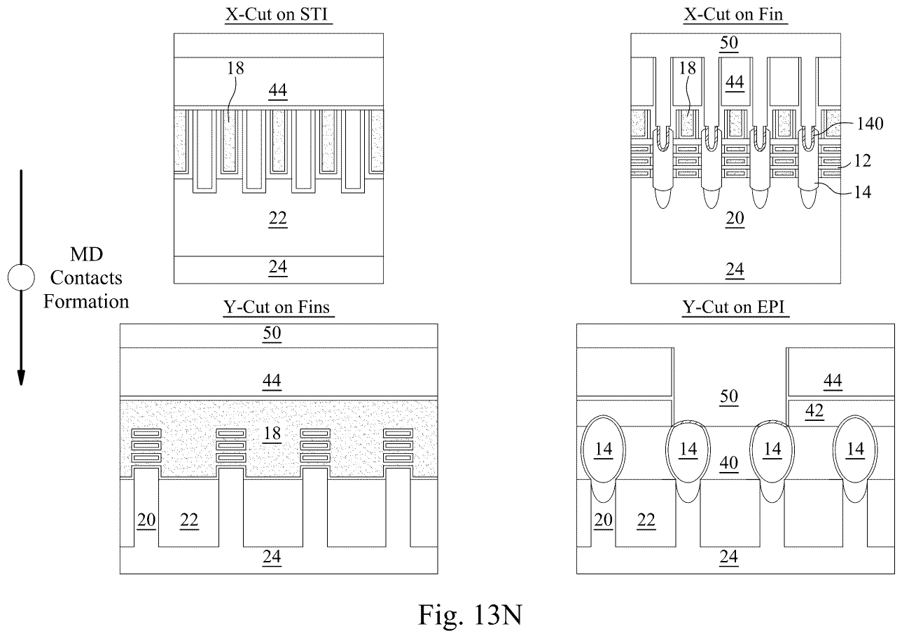

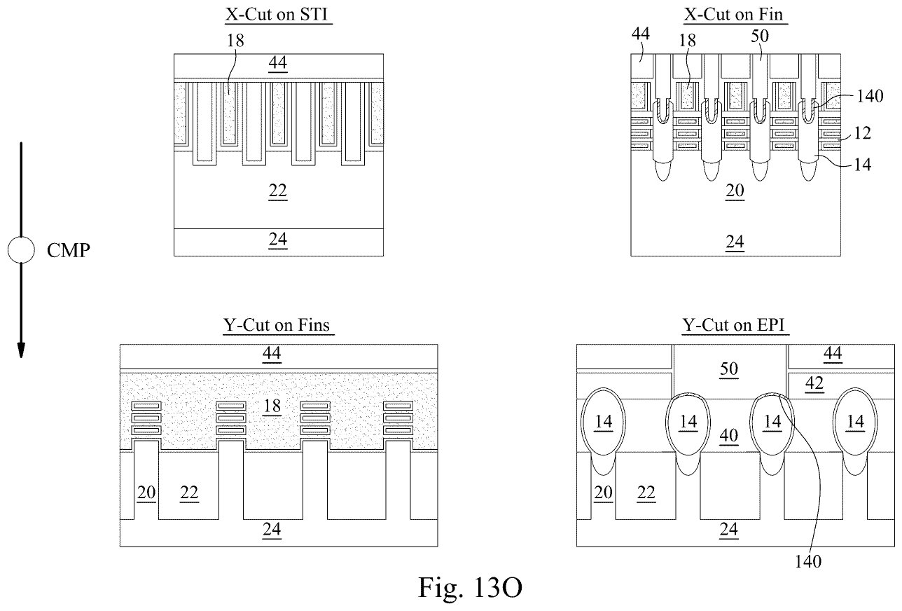

With reference now to FIGS. 13A, 13B, 13C, 13D, 13E, 13F, 13G, 13H, 13I, 13J, 13K, 13L, 13M, 13N, and 13O, a fabrication process for fabricating a 3D transistor array according to a nonlimiting illustrative embodiment is described. Each of FIGS. 13A, 13B, 13C, 13D, 13E, 13F, 13G, 13H, 13I, 13J, 13K, 13L, 13M, 13N, and 13O illustrate a successive point in the fabrication process by diagrammatically shown X-cut on STI, X-cut on Fin, Y-cut on Fins, and Y-cut on EPI views. The downward arrows on the left side of each of FIGS. 13A, 13B, 13C, 13D, 13E, 13F, 13G, 13H, 13I, 13J, 13K, 13L, 13M, 13N, and 13O labels the successive fabrication steps.

FIG. 13A diagrammatically illustrates the 3D transistor array under fabrication after formation of the 3D transistor structures including 3D channels 12 comprising semiconductor material, and S/D regions 14 connected with the 3D channels 12. The 3D channels 12 of the 3D transistor structures of FIG. 13A are gate-all-around (GAA) channels comprising stacks of semiconductor sheets, which at this stage of fabrication are spaced apart by sacrificial interposer layers 130 which are interposed between the semiconductor sheets of the 3D channels 12. While GAA transistor structures are shown by way of illustrative example, the 3D transistor structures may have other types of 3D channels, e.g., the 3D transistor structures may instead be FinFET transistors, 3D transistors employing a channel comprising a plurality of mutually parallel nanowires, or so forth. Also shown are the STI 22 and the fins 20 formed on the substrate 24 and on which the illustrative GAA channels 12 are disposed. At the stage shown in FIG. 13A, polycrystalline silicon (polysilicon) 132 and hard mask layers 134 have also been deposited and patterned. The polysilicon is a sacrificial material that will later be replaced by gate material in a metal gate (MG) deposition to form the gates of the 3D transistors. The hard mask 134 has been formed on the polysilicon 132 to protect it, and comprises one or more layers, e.g. silicon nitride and/or silicon oxide layers.

FIG. 13B diagrammatically illustrates the 3D transistor array under fabrication after further fabrication including removal of the hard mask 134 and deposition of the filler dielectric material 40. In some embodiments, the filler dielectric material 40 may be formed as a stack of two or more dielectric layers, such as first and second dielectric layers 40₁ and 40₂ as in the embodiments described herein with reference to FIGS. 7B, 7C, 7D, 8A, and 8B.

FIG. 13C diagrammatically illustrates the 3D transistor array under fabrication after chemical mechanical polishing (CMP) to remove excess filler dielectric material 40 and to planarize the surface.

FIG. 13D diagrammatically illustrates the 3D transistor array under fabrication after formation of recesses in the filler dielectric 40 to access the S/D regions 12.

FIG. 13E diagrammatically illustrates the 3D transistor array under fabrication after forming the mask material 42 on the S/D regions. In the illustrative example, the mask material 40 is deposited silicon nitride (SiN) material, e.g., deposited by chemical vapor deposition (CVD) or another suitable technique for the chosen mask material. In embodiments employing masking dielectric material 90 with doped outer or peripheral portions 92 (see FIG. 10 and related discussion), the processing forming the mask material also includes doping by dopant diffusion or another suitable doping technique. As seen in FIG. 13E, the mask material 14 fills the recesses formed in the filler dielectric material 40, so that the mask material 42 is formed on (and contacts) the S/D regions 14.

FIG. 13F diagrammatically illustrates the 3D transistor array under fabrication after CMP to remove excess mask material 42 and to planarize the surface.

FIG. 13G diagrammatically illustrates the 3D transistor array under fabrication after removal of the sacrificial polysilicon 132, preparatory to the MG deposition forming the gates of the 3D transistors. The etch performed to remove the polysilicon 132 is selective to remove polysilicon while not etching the mask material 42, and may for example employ a dry etching technique. As seen in FIG. 13G, this exposes the tops and sidewalls of the channels 12 extending between the S/D regions 14.

FIG. 13H diagrammatically illustrates the 3D transistor array under fabrication after oxide and interposer removal. In the GAA fabrication process, this step includes removal of the interposers 130 between the semiconductor sheets of the 3D channels 12. At this stage, the semiconductor sheets of the 3D channels 12 are suspended between supporting S/D regions 14 as best seen in the X-cut on Fin view, and the semiconductor sheets of the 3D channels 12 are now exposed on their tops, sidewalls, and bottoms, as best seen in the Y-cut on Fins view.

FIG. 13I diagrammatically illustrates the 3D transistor array under fabrication after formation of the metal gates 18 (or gate lines 18). For the illustrative GAA fabrication sequence, the gate formation employs CVD or another deposition technique that fills the gaps between the semiconductor sheets of the 3D channels 12 to provide gate-all-around contact between the gate 18 and the semiconductor sheets of the illustrative GAA channels 12.

FIG. 13J diagrammatically illustrates the 3D transistor array under fabrication after CMP to remove excess gate material and to planarize the surface. As seen in FIG. 13J, this CMP exposes the upper surface of the mask material 42.

FIG. 13K diagrammatically illustrates the 3D transistor array under fabrication after disposing the at least one dielectric layer 44 over the mask material 42 and over the 3D transistor structures, and over the gates 18. The at least one dielectric layer 44 may also be considered an interlayer dielectric (ILD) material 44 in some embodiments.

FIG. 13L diagrammatically illustrates the 3D transistor array under fabrication after the MD etch; that is, after etching the at least one dielectric material 44 and the mask material 42 to open access recesses 45 through the at least one dielectric layer 44 accessing the S/D regions 14. This etching also etches the convex upper surfaces of the S/D regions 14 to form etch-modified upper surfaces of the S/D regions 14, e.g., with concave upper surface portions 32 having concave curvature in the X-direction as seen in the X-cut on Fin view, and as previously described herein with reference to FIGS. 2 and 3 (or as in alternative embodiments of FIGS. 9 and 10). This produces the upper cavities 34 in the S/D regions 14 which advantageously provide increased contact area for the source/drain contacts to the S/D regions 14 while limiting MD-MG parasitic capacitance, a previously described herein.

With particular reference to the Y-cut on EPI view of FIG. 13L, the MD etch also modifies curvature of the upper surfaces of the S/D regions 14 along the Y-direction as previously described with reference to FIGS. 6A and 6B, to reduce the concavity or flatten the curvature in the Y-direction so that the modified concave upper surface portions 32 have a saddle shape. As also seen in the Y-cut on EPI view, the MD etch leaves a portion of the filler dielectric layer 40 disposed between the adjacent S/D regions 14 (i.e., adjacent along the Y-direction) to provide a reduced recess or no recess in the dielectric filler material 40 between the adjacent S/D regions 14 after the MD etch, thus advantageously reducing MG-MD parasitic capacitance.

FIG. 13M diagrammatically illustrates the 3D transistor array under fabrication after optional formation of a silicide layer 140 on the upper surfaces of the S/D regions 14 exposed by the MD etch of FIG. 13L. The optional silicide layer 140 is applied via the access recesses 45, and improve robustness of the MD contacts to the S/D regions 14. The silicide layer 140 is seen in the X-cut on Fin and Y-cut on EPI views of FIG. 13M.

FIG. 13N diagrammatically illustrates the 3D transistor array under fabrication after formation of the source and drain metal or other source and drain contacts (MD contacts) 50. This includes filling the access recesses 45 with an electrically conductive material to form the S/D contacts 50 to the etch-modified upper surfaces 32 of the S/D regions 14. In the illustrative embodiment of FIG. 13N, the S/D contacts 50 to the etch-modified upper surfaces 32 of the S/D contacts 14 include the silicide layer 140 which improves the conductive interface between the S/D contacts 50 and the epitaxial silicon of the S/D contacts 14.

FIG. 13O diagrammatically illustrates the 3D transistor array under fabrication after CMP to remove excess MD contact and to planarize the surface. Although not shown, there may be subsequent processing, such as (by way of nonlimiting example) back end-of-line (BEOL) processing to form metallization layers electrically interconnecting the 3D transistors to each other and/or to other electronic components of an integrated circuit (IC) under fabrication which includes the 3D transistors.

In the following, some further embodiments are described.

In a nonlimiting illustrative embodiment, a method of fabricating three-dimensional (3D) transistors includes: forming 3D transistor structures including 3D channels comprising semiconductor material and source and drain (S/D) regions connected with the 3D channels; forming mask material on the S/D regions; disposing at least one dielectric layer over the mask material and over the 3D transistor structures; etching the at least one dielectric material and the mask material to open access recesses through the at least one dielectric layer accessing the S/D regions, the etching also etching upper surfaces of the S/D regions to form etch-modified upper surfaces of the S/D regions; and filling the access recesses with an electrically conductive material to form S/D contacts to the etch-modified upper surfaces of the S/D regions.

In a nonlimiting illustrative embodiment, a method of fabricating three-dimensional (3D) transistors includes: forming 3D transistor structures including 3D channels comprising semiconductor material and source and drain (S/D) regions connected with the 3D channels, wherein the S/D regions have convex upper surfaces; forming mask material on the S/D regions; disposing at least one dielectric layer over the mask material and over the 3D transistor structures; etching the at least one dielectric material and the mask material to open access recesses through the at least one dielectric layer accessing the S/D regions, the etching also etching the convex upper surfaces of the S/D regions to form etch-modified upper surfaces of the S/D regions; and filling the access recesses with an electrically conductive material to form S/D contacts to the etch-modified upper surfaces of the S/D regions.

In a nonlimiting illustrative embodiment, a 3D transistor array includes: 3D channels comprising semiconductor material extending along an X-direction; a gate line extending along a Y-direction transverse to the X-direction, the gate line including gates extending at least partway around corresponding 3D channels; S/D regions connected with the 3D channels; a cut metal gate (CMG) dielectric structure extending along the X-direction between adjacent S/D regions which are adjacent along the Y-direction, the CMG dielectric structure having a height that is greater than or equal to a maximum height of the gate line; and S/D contacts comprising electrically conductive material that is disposed over the adjacent S/D regions and over the portion of the CMG dielectric structure extending between adjacent S/D regions.

In a nonlimiting illustrative embodiment, a method of fabricating 3D transistors includes: forming 3D transistor structures including 3D channels comprising semiconductor material and source and drain (S/D) regions connected with the 3D channels; disposing a filler dielectric material between adjacent S/D regions which are adjacent along the direction transverse to the 3D channels; forming mask material on the S/D regions and on the filler dielectric material; forming gates extending at least partway around corresponding 3D channels; disposing at least one dielectric layer over the mask material, the gates, and the 3D transistor structures; etching the at least one dielectric material and the mask material to open access recesses through the at least one dielectric layer accessing the S/D regions, the etching leaving a portion of the filler dielectric layer disposed between the adjacent S/D regions at a height greater than or equal to a maximum height of the gates; and filling the access recesses with an electrically conductive material to form S/D contacts to the etch-modified upper surfaces of the S/D regions, the electrically conductive material also being disposed over the portion of the filler dielectric layer left by the etching at a height greater than or equal to the maximum height of the gates.

In a nonlimiting illustrative embodiment, fabrication of 3D transistors includes forming 3D transistor structures including 3D channels and S/D regions connected with the 3D channels. The S/D regions have convex upper surfaces. Mask material is formed on the S/D regions. At least one dielectric layer is disposed over the mask material and over the 3D transistor structures. The at least one dielectric material and the mask material are etched to open access recesses through the at least one dielectric layer accessing the S/D regions. The etching also etching the convex upper surfaces of the S/D regions to form etch-modified upper surfaces of the S/D regions. The access recesses are filled with an electrically conductive material to form S/D contacts to the etch-modified upper surfaces of the S/D regions. The etch-modified upper surfaces may have concave curvature parallel with the 3D channels, and may also have flattened or less convex transverse curvature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating three-dimensional transistors, the method comprising:
forming three-dimensional (3D) transistor structures including 3D channels comprising semiconductor material and source and drain (S/D) regions connected with the 3D channels;
forming mask material on the S/D regions;
disposing at least one dielectric layer over the mask material and over the 3D transistor structures;
etching the at least one dielectric material and the mask material to open access recesses through the at least one dielectric layer accessing the S/D regions, the etching also etching upper surfaces of the S/D regions to form etch-modified upper surfaces of the S/D regions; and
filling the access recesses with an electrically conductive material to form S/D contacts to the etch-modified upper surfaces of the S/D regions.

2. The method of claim 1, wherein:
the S/D regions have convex upper surfaces, and
the etching of the at least one dielectric material and the mask material to open the access recesses through the at least one dielectric also etches the convex upper surfaces of the S/D regions to form etch-modified upper surfaces of the S/D regions.

3. The method of claim 2, wherein:
the etching forms the etch-modified upper surfaces of the S/D regions including concave upper surface portions of the S/D regions with concave curvature along a direction parallel with the 3D channels, the concave upper surface portions partially surrounding corresponding upper cavities formed in the S/D regions by the etching; and
the filling of the access recesses with the electrically conductive material to form the S/D contacts includes filling the upper cavities formed in the S/D regions with the electrically conductive material.

4. The method of claim 3, wherein the etching has a faster etch rate for the S/D regions than for the mask material.

5. The method of claim 4, wherein the mask material formed on the S/D regions has a smaller lateral dimension along the direction parallel with the 3D channels than a lateral dimension of the S/D regions along the direction parallel with the 3D channels.

6. The method of claim 4, wherein the S/D regions comprise epitaxially deposited silicon, and the mask material comprises silicon nitride.

7. The method of claim 3, wherein the forming of the mask material on the S/D regions includes:
disposing a masking dielectric material on the S/D regions; and
doping an outer portion of the masking dielectric material with a dopant that is effective to reduce an etch rate of the etching for the doped outer portion of the masking dielectric material.

8. The method of claim 3, wherein the convex upper surfaces of the S/D regions prior to the etching have a height Δh; and
the upper cavities formed in the S/D regions by the etching have a depth h which is a monotonically increasing function of the height Δh of the convex upper surfaces of the S/D regions prior to the etching.

9. The method of claim 3, wherein the concave upper surface portions of the S/D regions are flattened in a direction transverse to the 3D channels compared with a convexity in the direction transverse to the 3D channels of the convex upper surfaces of the S/D regions prior to the etching.

10. The method of claim 1, further comprising:
prior to the forming of the mask material, disposing a filler dielectric material between adjacent S/D regions which are adjacent along the direction transverse to the 3D channels, wherein the forming of the mask material on the S/D regions also forms the mask material on the filler dielectric material; and
before the disposing of the at least one dielectric layer over the mask material and over the 3D transistor structures, forming gates extending at least partway around corresponding 3D channels;
wherein the etching leaves a portion of the filler dielectric layer disposed between the adjacent S/D regions at a height greater than or equal to a maximum height of the gates.

11. The method of claim 10, wherein the etching includes:
first patterned etching of the at least one dielectric material and the mask material to open the access recesses; and
second patterned etching to reduce the height of the filler dielectric layer disposed between the adjacent S/D regions.

12. The method of claim 11, wherein the disposing of the at least one dielectric layer over the mask material and over the 3D transistor structures includes:
disposing a first dielectric layer having a height greater than or equal to a maximum height of the gates;
disposing an etch stop layer over the first dielectric layer; and
disposing a second dielectric layer over the etch stop layer.

13. The method of claim 1, further comprising:
prior to the forming of the mask material, disposing a filler dielectric material between adjacent S/D regions which are adjacent along the direction transverse to the 3D channels;
after the disposing of the at least one dielectric layer over the mask material and over the 3D transistor structures, forming a gate line along the direction transverse to the 3D channels, the gate line including gates extending at least partway around corresponding 3D channels;
after forming the gate line, forming a cut metal gate (CMG) dielectric structure which cuts the gate line, the CMG dielectric structure also extending between the adjacent S/D regions, the CMG dielectric structure having a height that is greater than or equal to a maximum height of the gate line;
wherein the etching does not etch the CMG dielectric structure.

14. A three-dimensional (3D) transistor array comprising:
3D channels comprising semiconductor material extending along an X-direction;
a gate line extending along a Y-direction transverse to the X-direction, the gate line including gates extending at least partway around corresponding 3D channels;
source and drain (S/D) regions connected with the 3D channels;
a cut metal gate (CMG) dielectric structure extending along the X-direction between adjacent S/D regions which are adjacent along the Y-direction, the CMG dielectric structure having a height that is greater than or equal to a maximum height of the gate line; and
S/D contacts comprising electrically conductive material that is disposed over the adjacent S/D regions and over the portion of the CMG dielectric structure extending between adjacent S/D regions.

15. The 3D transistor array of claim 14, wherein the adjacent S/D contacts have concave upper surfaces which have a concave curvature along the X-direction.

16. The 3D transistor array of claim 15, wherein the adjacent S/D contacts have a convex curvature along the Y-direction.

17. A method of fabricating three-dimensional transistors, the method comprising:
forming three-dimensional (3D) transistor structures including 3D channels comprising semiconductor material and source and drain (S/D) regions connected with the 3D channels;
disposing a filler dielectric material between adjacent S/D regions which are adjacent along the direction transverse to the 3D channels;
forming mask material on the S/D regions and on the filler dielectric material;
forming gates extending at least partway around corresponding 3D channels;
disposing at least one dielectric layer over the mask material, the gates, and the 3D transistor structures;
etching the at least one dielectric material and the mask material to open access recesses through the at least one dielectric layer accessing the S/D regions, the etching leaving a portion of the filler dielectric layer disposed between the adjacent S/D regions at a height greater than or equal to a maximum height of the gates; and
filling the access recesses with an electrically conductive material to form S/D contacts to the etch-modified upper surfaces of the S/D regions, the electrically conductive material also being disposed over the portion of the filler dielectric layer left by the etching at a height greater than or equal to the maximum height of the gates.

18. The method of claim 17, wherein the etching includes:
first patterned etching of the at least one dielectric material and the mask material to open the access recesses; and
second patterned etching to reduce the height of the filler dielectric layer disposed between the adjacent S/D regions, the second patterned etching leaving the portion of the filler dielectric layer disposed between the adjacent S/D regions at the height greater than or equal to the maximum height of the gates.

19. The method of claim 18, wherein the disposing of the at least one dielectric layer over the mask material and over the 3D transistor structures includes:
disposing a first dielectric layer having a height greater than or equal to a maximum height of the gates;
disposing an etch stop layer over the first dielectric layer; and
disposing a second dielectric layer over the etch stop layer.

20. The method of claim 17, wherein:
after forming the 3D transistor structures, the S/D regions have convex upper surfaces; and
the etching forms concave recesses in the S/D regions having concave curvature along a direction of the 3D channels.
